(19) United States
(12) Patent Application Publication
(10) Pub. No.: US 2006/0237828 A1
(43) Pub. Date: Oct. 26, 2006

(54) System and method for enhancing wafer chip scale packages

(76) Inventors: William Dale Robinson, Rockwall, TX (US); Sreenivasan K. Koduri, Allen, TX (US)

Correspondence Address: TEXAS INSTRUMENTS INCORPORATED, P O BOX 655474, M/S 3999, DALLAS, TX, 75265, US

(21) Appl. No.: 11/112,336

(22) Filed: Apr. 22, 2005

(51) Int. Cl. H01L 23/02

(52) U.S. Cl. 257/678

(57) ABSTRACT

System and method for enhancing the performance of wafer chip scale packages (WCSP). A preferred embodiment comprises a parent electrical device 305 and a daughter electrical device 310 coupled to a bottom surface of the parent electrical device, wherein the bottom surface is also used to attach the parent electrical device to a circuit board. A passivation layer is formed over the daughter electrical device to protect it from environmental dangers. The passivation layer also prevents the detachment of the daughter electrical device when the parent electrical device is attached to the circuit board. Solder bumps attached to the parent electrical device permit the attachment of the parent electrical device to the circuit board. The inclusion of the daughter electrical device can add desired functionality as well as permit the use of optimized fabrication processes for different types of integrated circuitry.

### TECHNICAL FIELD

The present invention relates generally to a system and method for integrated circuit packaging, and more particularly to a system and method for enhancing the performance of wafer chip scale packages.

### BACKGROUND

Integrated circuit (IC) packaging plays a vital role in the continued development of integrated circuits. The IC packaging provides a measure of protection for the ICs and can be a significant factor in the overall performance of the IC. The size of the IC package can dictate the final size of the electronic device containing the IC, since the electronic device must be large enough to contain the packaged IC. However, if the packaging becomes too small, the manufacture of the electronic device can become difficult. Furthermore, an insufficiently sized package may not be able to provide adequate protection for the IC that it contains. Therefore, there is a continual drive to reduce the size of IC packaging while maintaining ease in manufacturing.

Wafer chip scale packaging (WCSP) is a packaging technique wherein solder bumps (or similarly, solder balls and so forth) can be directly attached to the semiconductor die (or electrical component) and, after flipping, can then be mounted onto a circuit board. WCSP offers a compact package for integrated circuits with small to medium input/output pin requirements. Protection of the IC in the WCSP can be realized through the use of passivation layers, such as those made from various polymers, mold compounds, organic materials, and so on. For large ICs, the use of WCSP may not be ideal since the packaging does not offer measures to ensure the stability of the large IC in situations such as flexing of the circuit board. Thus, difficulty may be encountered when using WCSP with large ICs. Hence, a limit may be in place on the functionality of ICs packaged using WCSP.

A technique that can be used to provide desired functionality within a limited die size is to decrease the feature size of the components in the integrated circuit. By decreasing the feature size, additional circuitry can be added to the die, thereby increasing ftunctionality without affecting the die size.

One disadvantage of the prior art is that the manufacturing processes that are used to make small feature sized components can be expensive. This can increase the cost of the ICs. The increased cost must then be passed onto the customers or absorbed by the manufacturer. Increased cost ICs may not be viable in low-cost applications such as low-end consumer electronics or cellular telephones.

A second disadvantage of the prior art is that an IC is usually manufactured using a single process. Therefore, it can be difficult to optimize the performance of the IC when there are different types of circuitry on the IC, since a manufacturing process may be better suited in the making one type of circuitry over another. For example, one manufacturing process may be ideal for fabricating low-noise amplifiers while another is better for analog circuits. The use of a single manufacturing process may then require a compromise design that does not perform as well as if the individual types of circuitry were optimized by using different fabrication processes.

### SUMMARY OF THE INVENTION

These and other problems are generally solved or circumvented, and technical advantages are generally achieved, by preferred embodiments of the present invention which provides a system and method for enhancing the performance of WCSP ICs.

In accordance with a preferred embodiment of the present invention, an enhanced packaged integrated circuit is provided. The enhanced packaged integrated circuit includes a parent electrical device configured to perform a first desired function, a daughter electrical device coupled to the parent electrical device. The daughter electrical device is configured to perform a second desired function. The daughter electrical device is coupled to a bottom surface of the parent electrical device that also contains electrical contacts used to attach the parent electrical device to a circuit board. A passivation layer is applied over the daughter electrical device, the passivation layer fixes the daughter electrical device to the parent electrical device. The daughter electrical device has plurality of solder contacts that couple to the electrical contacts on the parent electrical device. The plurality of solder contacts permit the attachment of the enhanced packaged integrated circuit to the circuit board.

In accordance with another preferred embodiment of the present invention, a method for manufacturing an enhanced packaged integrated circuit is provided. The method includes partially fabricating a parent component. The fabrication stops at a stage prior to a completion of the fabrication of the parent component. A daughter component is attached onto a bottom surface of the parent component. The daughter component is attached to the parent board via a plurality of solder contacts mounted onto the daughter component. The method further includes depositing a first passivation layer over the daughter component and the parent component, and completing the fabrication of the parent component.

In accordance with another preferred embodiment of the present invention, a method for manufacturing an enhanced packaged integrated circuit is provided. The method includes attaching a first component onto a second component. The first component is attached to a bottom surface of the second component via a plurality of electrical contacts mounted onto the first component. A passivation layer is deposited over the first component and the bottom surface of the second component. Functionality of the second component can be tested and external electrical contacts are placed on electrical contact points of the second component if the second component passes functional testing.

In accordance with another preferred embodiment of the present invention, an integrated circuit is provided. The integrated circuit includes a parent device and a daughter device attached to a bottom surface of the parent device. The daughter device is attached via a set of contact points to a set of contact pads located in a center portion of the bottom surface, with the set of contact points making electrical contact with the set of contact pads. A passivation layer fixes the daughter device to the bottom surface, and a second set of contact points electrically connected to a second set of contact points along a periphery of the bottom surface.

An advantage of a preferred embodiment of the present invention is that the addition of a daughter board can permit the addition of additional functionality without increasing the footprint of a WCSP IC.

A further advantage of a preferred embodiment of the present invention is that the use of a daughter board can permit the optimization of the manufacture of the daughter board (and the parent board) to optimize the function of the different circuits in the WCSP IC.

Yet another advantage of a preferred embodiment of the present invention is that it can permit the attachment of a daughter board that may actually contain active circuitry to passive components, such as inductors, capacitors, and so forth, serving as the parent board. The active circuitry can then be hidden underneath passive components on the circuit board. Alternatively, the parent board may contain the active circuitry while the daughter board contains passive components.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a and 1b are diagrams of exemplary WCSPs;

FIG. 2 is a diagram of an enhanced WCSP;

FIG. 3 is a diagram of a further enhanced WCSP, according to a preferred embodiment of the present invention;

FIG. 4 is a diagram of an enhanced WCSP with a redistributing layer, according to a preferred embodiment of the present invention;

FIG. 5 is a diagram of an enhanced WCSP with a daughter IC that can be attached to a circuit board, according to a preferred embodiment of the present invention;

FIG. 6 is a diagram of an enhanced WCSP with a daughter IC that can be attached to a circuit board as well as a redistributing layer, according to a preferred embodiment of the present invention;

FIG. 7 is a diagram of an enhanced WCSP with a plurality of daughter ICs, according to a preferred embodiment of the present invention; and

FIG. 8 is a diagram of a sequence of events in the manufacture of an enhanced WCSP, according to a preferred embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely an integrated circuit (IC) packaged using a wafer chip scale package (WCSP). The invention may also be applied, however, to other IC packaging, such as ball grid array (BGA), as well as pin grid array (PGA) and land grid array (LGA), as examples.

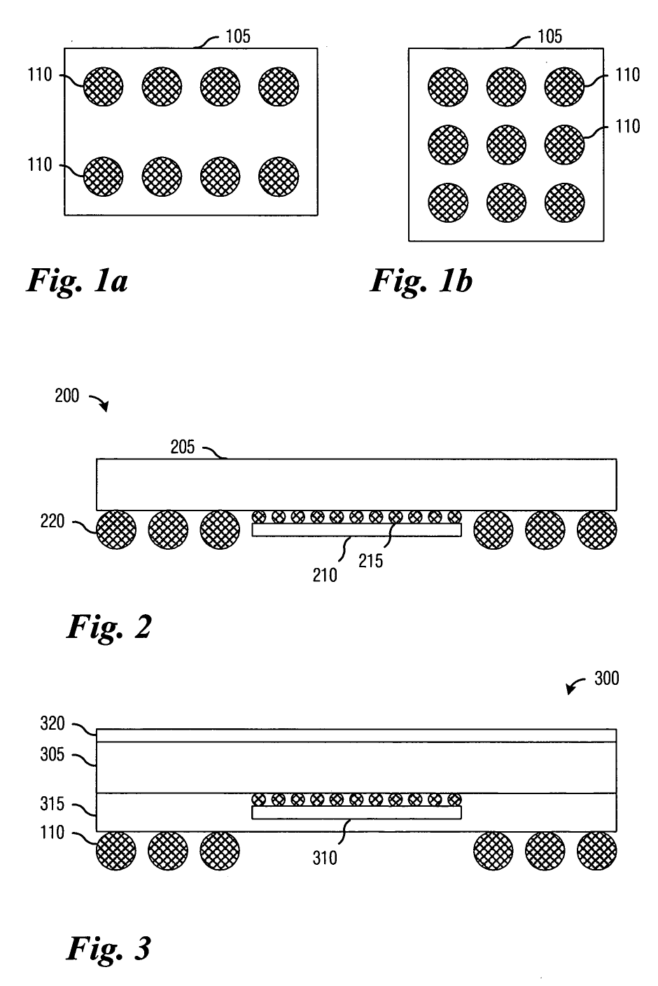

With reference now to FIGS. 1a and 1b, there are shown diagrams illustrating exemplary WCSP ICs. The diagrams shown in FIGS. 1a and 1b illustrate bottom views of ICs that have been packaged using WCSP. An IC packed with WCSP comprises a die 105 and a plurality of solder bumps 110. The die 105 contains integrated circuitry that performs a desired function. Along with components making up the integrated circuitry, pads (not shown) are located on the die 105. The pads can be used to hold the solder bumps 110. Once the solder bumps 110 are attached to the die 105, the WCSP is complete. To attach the WCSP IC to a circuit board, the WCSP IC is flipped and then lowered onto appropriate locations on the circuit board and soldered into place. WCSP ICs have an advantage in that the packaged ICs are no larger than the IC dies themselves.

However, since a WCSP IC is typically protected from damage with nothing more than a passivation layer, large ICs are usually not good candidates for WCSP, since there is nothing in the packaging to help provide structural rigidity to the IC as well as protection from physical damage. Therefore, there may be a limit to the size of die that can be used with WCSP.

With reference now to FIG. 2, there is shown a diagram illustrating an enhanced WCSP IC 200. The enhanced WCSP IC 200 features a parent IC 205 that can substantially be a standard die, such as the die 105 (FIGS. 1a and 1b), with an exception that sufficient space has been provided on the parent IC 205 so that a daughter IC 210 can be attached. The daughter IC 210 can be attached to the parent IC 205 using solder bumps 215. The solder bumps 215 make electrical contact with contact pads located on the parent IC 205. Note that since the daughter IC 210 is being attached to the parent IC 205 without having to meet any circuit board manufacturing standards, the solder bumps 215 may be smaller (and located closer together) than solder bumps 220 that are used to attach the enhanced WCSP IC 200 to a circuit board. In other words, the enhanced WCSP IC 200 can be attached to the circuit board using solder balls, land pads, pins, leads, or so forth. Furthermore, the manufacturing process used to manufacture the enhanced WCSP IC 200 is likely to be more stringent than the circuit board manufacturing process, therefore, tolerances can be made tighter. Note that although FIG. 2 displays a single daughter IC being attached to the parent IC 205, a plurality of daughter ICs (perhaps of varying footprint and function) can be attached to the parent IC 205, as long as sufficient space is available.

As discussed earlier, the use of the daughter IC 210 and the parent IC 200 can permit the use of different manufacturing processes that can be optimized to the circuitry on the different ICs. For example, if the daughter IC 210 contains analog circuitry, a manufacturing process that produces high quality analog ICs (or low-noise amplifier circuitry, and so forth) can be used to manufacture the daughter IC 210, while a manufacturing process optimized for the circuitry located on the parent IC 205 can be used to manufacture the parent IC 205. Additionally, although the parent IC 205 and the daughter IC 210 are referred to as being ICs, discrete components can replace either in actual practice. For example, a large monolithic capacitor (or inductor, resistor, and so on) can take the place of the parent IC 205 while the daughter IC 210 can contain the circuitry that makes use of the monolithic component, and vice versa. When passive components, such as capacitors, inductors, resistors, and so forth, are used in place of either the parent IC 205 or the daughter IC 210, the resulting packaged integrated circuit can still be referred to as being an enhanced wafer chip scale packaged IC.

With reference now to FIG. 3, there is shown a diagram illustrating an enhanced WCSP IC 300, according to a preferred embodiment of the present invention. The enhanced WCSP IC 200 (FIG. 2) discussed previously may encounter manufacturing problems when it is being soldered to a circuit board. The heat required to melt the solder and bond the WCSP IC 200 to the circuit board may also melt the solder that is holding the daughter IC 210 (FIG. 2) to the parent IC 205 (FIG. 2). The enhanced WCSP IC 300 provides a solution for this potential problem. The enhanced WCSP IC 300 features a parent IC 305 that can permit the attachment of a daughter IC 310 (or a plurality of daughter ICs) via the use of solder. However, the daughter IC 310 can be covered with a passivation layer 315 after the daughter IC 310 has been bonded to the parent IC 305. The passivation layer 315 can also be referred to as an encapsulation layer. According to a preferred embodiment of the present invention, the passivation layer 315 can be made from various polymers, mold compounds, organic materials, and so forth. The passivation layer 315 can bond the daughter IC 310 to the parent IC 305 with a bond that is not as temperature dependent as the solder. Therefore, when the enhanced WCSP IC 300 is bonded to the circuit board, the daughter IC 310 will not come lose. As discussed previously, the enhanced WCSP IC 300 can be attached to the circuit board using solder balls, land pads, pins, leads, or so forth.

Since the parent IC 305 is substantially unprotected, an optional backside coating (or metallization layer) 320 can be applied. The backside coating 320 can provide a physical barrier to protect the parent IC 305 from damage as well as providing a barrier to light which may cause unintended production of electrical currents. A metallization layer can also function as the backside coating 320 with an added benefit of being able to provide good thermal transfer if a heat sink was to be attached to the enhanced WCSP IC 300.

With reference now to FIG. 4, there is shown a diagram illustrating an enhanced WCSP IC 400, according to a preferred embodiment of the present invention. The enhanced WCSP IC 300 (FIG. 3) had a plurality of solder bumps 110 arranged around the daughter IC 310. A reason for this is that the necessity of leaving room for the daughter IC 310 prevented the routing of conductors through the surface of the parent IC 305. The absence of conductors in the area occupied by the daughter IC 310 can then prevent the inclusion of solder bumps 110 after the passivation layer 315 is formed. According to a preferred embodiment of the present invention, after the passivation layer 315 is formed in the enhanced WCSP IC 400, a redistribution layer 405 can be formed that can permit conductors 410 to be routed over the area occupied by the daughter IC 310. The presence of the conductors 410 can permit the presence of the solder bumps all over the surface of the enhanced WCSP IC 400. A second passivation layer 415 may be needed to electrically separate the conductors 410 from the solder bumps. Note that while the diagram in FIG. 4 displays a single redistribution layer 405, multiple redistribution layers can be formed if multiple routing layers are needed.

With reference now to FIG. 5, there is shown a diagram illustrating an enhanced WCSP IC 500, according to a preferred embodiment of the present invention. It may be possible that the daughter IC 310 of the enhanced WCSP IC 500 has high power dissipation requirements (for example, the daughter IC 310 may carry a large number of high-gain amplifiers). If such an IC is embedded into a passivation layer, it can be possible for the IC to overheat due to poor heat dissipation. In such a situation, the daughter IC 310 may be partially embedded in the passivation layer 315 so that one surface of the daughter IC 310 can be coated with a metalized layer 505 that can make thermal contact with the circuit board (or a heat sink) to help the dissipation of the heat generated by the daughter IC 310. Note that it may be necessary to increase the thickness of the daughter IC 310 so that solid contact can be made with both the parent IC 305 and the circuit board (or heat sink).

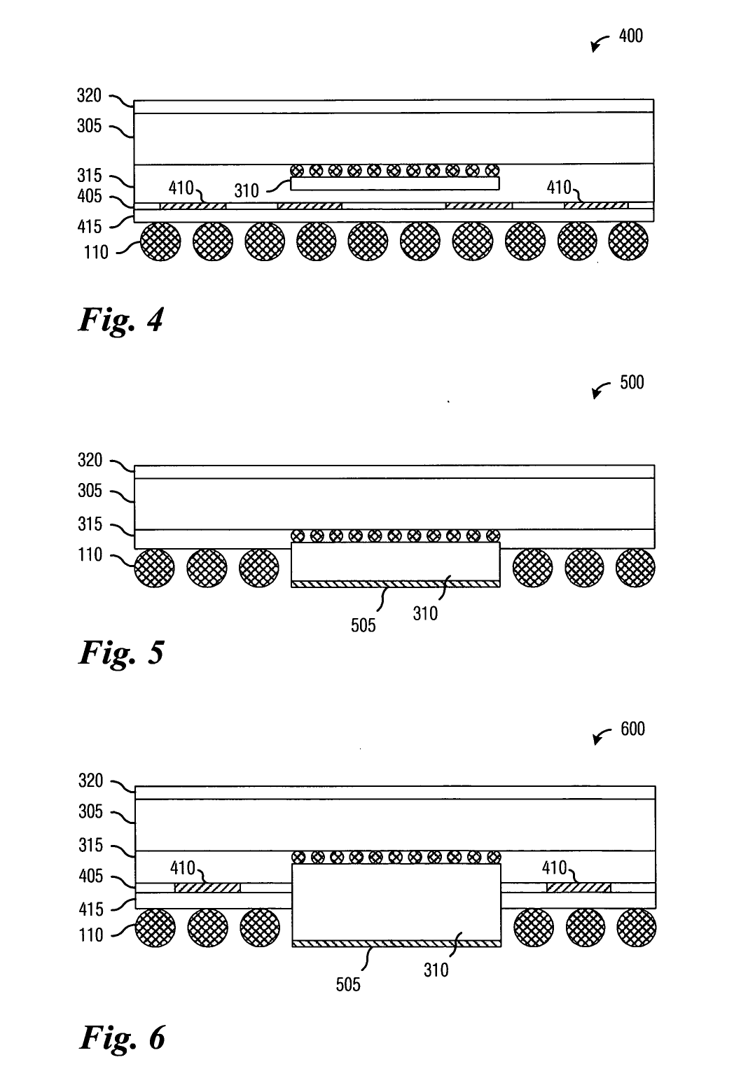

With reference now to FIG. 6, there is shown a diagram illustrating an enhanced WCSP IC 600, according to a preferred embodiment of the present invention. The presence of the redistribution layer 405 and conductors 410 enable additional signal routing to take place in the enhanced WCSP IC 600. The enhanced WCSP IC 600 is similar to the enhanced WCSP IC 400 (FIG. 4). However, since the daughter IC 310 extends beyond the passivation layer 315 and all the way to the circuit board, the solder bumps 11O cannot be placed in the area consumed by the daughter IC 310.

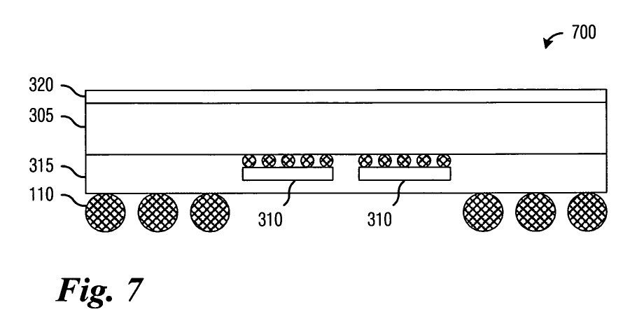

With reference now to FIG. 7, there is shown a diagram illustrating an enhanced WCSP IC 700, according to a preferred embodiment of the present invention. Circumstances may arise where multiple daughter ICs 310 may be needed or desired. For example, the multiple daughter ICs 310 may permit optimization for certain circuit types or large, passive circuit components (such as capacitors, inductors, and so forth) which can be difficult to fabricate and which can be added to the parent IC 305. As long as there is sufficient room on the surface of the parent IC 305 for the daughter ICs 310, there is no limit to the number of daughter ICs 310 that can be placed on the parent IC 305. Additional constraints on the number of daughter ICs can include adequate area for the solder bumps 110 (however, this can be alleviated with the use of redistribution layers and conductors, such as shown in FIGS. 4 and 5), adequate area on the parent IC 305 to form contacts for the daughter ICs 310, and so forth.

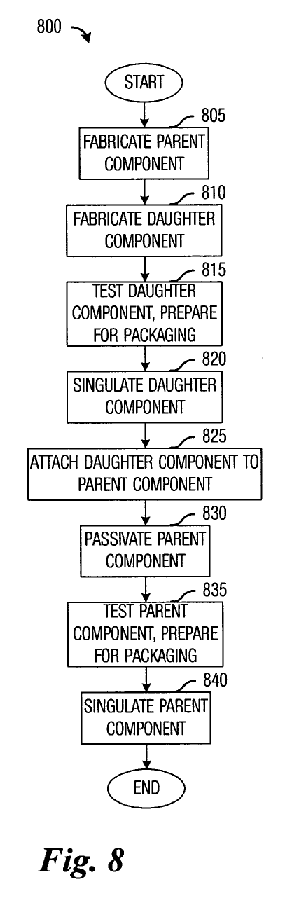

With reference now to FIG. 8, there is shown a diagram illustrating a sequence of events 800 in the manufacture of an enhanced WCSP IC, according to a preferred embodiment of the present invention. According to a preferred embodiment of the present invention, the sequence of events 800 shown in FIG. 8 can be used for the manufacture of an enhanced WCSP IC that does not feature a redistribution layer or conductors, such as the redistribution layer 405 and the conductors 410 shown in FIG. 4 and FIG. 6. However, it should be readily evident to those of ordinary skill in the art of the present invention that these features can be readily added to an enhanced WCSP IC.

The sequence of events 800 can begin with the fabrication of a plurality of parent ICs, such as the parent IC 305 (block 805). Note while that the discussion refers to the fabrication of ICs, either parent IC or daughter IC, it is possible that passive components can be used in place of either the parent IC or the daughter IC. Therefore, the use of the term IC (or integrated circuit) should not be construed as being limiting to the scope of the present invention. The fabrication of the parent ICs can proceed as far as necessary to get the parent ICs into a condition where they are ready to accept the attachment of daughter ICs, such as the daughter IC 310. If the fabrication of the parent ICs were to proceed to completion prior to the attachment of the daughter ICs, then it may be impossible to properly attach the daughter ICs and form proper electrical connections, resulting in an enhanced WCSP IC that would not be able to operate properly. In addition to fabricating the parent ICs, the daughter ICs can also be separately fabricated (block 810). The fabrication of the daughter ICs can continue to completion with the testing of the daughter ICs and the packaging of the operational daughter ICs (block 815) and the singulating of the packaged daughter ICs (block 820). Note that the fabrication, test, and packaging of the daughter ICs (block 810, 815, and 820) may occur at a different fabrication location and use a different fabrication process than that of the parent ICs. Additionally, it may be possible to change the order of some of the events. For example, a manufacturing process may be used wherein the daughter ICs may be packaged prior to being tested. Furthermore, the daughter ICs (or parent ICs) can be fabricated at an earlier time and stored until needed.

After the daughter ICs have been singulated (block 820), the daughter ICs can be attached to the parent ICs (block 825). After attachment, the parent ICs can be completed with the addition of a passivation layer (block 830). Additionally, if additional layers are needed, such as the redistribution layer and conductors, these additional layers can be added after the attachment of the daughter ICs (block 825). After the attachment of the daughter ICs and the addition of the passivation layer (or additional layers), the parent ICs can be tested and the parent ICs that tested operational can be packaged (block 835). The parent ICs can then be singulated (block 840). The completed parent ICs, which actually contain the parent ICs with attached daughter ICs, are singulated and are now enhanced WCSP ICs and can be used or packaged to be sold.

The sequence of events 800 illustrates an enhanced WCSP IC wherein both the parent ICs and the daughter ICs are integrated circuits and are singulated from a wafer. However, it is possible that one of the ICs (either a parent IC or a daughter IC) or both ICs do not contain active circuits. Therefore, in this instance, singulation is not necessary. It is possible to have passive components replace one or both of the parent IC and daughter IC. These passive components, such as capacitors, inductors, resistors, and so forth may be mounted directly onto either the parent IC or daughter IC. The replacement of the parent IC or daughter IC with passive components do not significantly change the sequence of events 800, with a possible exception in not requiring that the passive components be singulated.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An enhanced packaged integrated circuit comprising:
a parent electrical device configured to perform a first desired function;
a daughter electrical device coupled to the parent electrical device, the daughter electrical device being configured to perform a second desired function, wherein the daughter electrical device is coupled to a bottom surface of the parent electrical device that also contains a plurality of electrical contacts used to attach the parent electrical device to a circuit board, wherein at least one of the parent electrical device or the daughter electrical device comprises an integrated circuit;
a passivation layer applied over the daughter electrical device, the passivation layer to fix the daughter electrical device to the parent electrical device; and
a plurality of solder contacts coupled to the electrical contacts on the parent electrical device, the plurality of solder contacts to permit the attachment of the enhanced packaged integrated circuit to the circuit board.

2. The enhanced packaged integrated circuit of claim 1, wherein the passivation layer covers both the bottom surface of the parent electrical device and the daughter electrical device.

3. The enhanced packaged integrated circuit of claim 1, wherein the parent electrical device is formed using a first fabrication process technology, and wherein the daughter electrical device is formed using a second fabrication process technology that is different from the first fabrication process technology.

4. The enhanced packaged integrated circuit of claim 1, wherein the parent electrical device is a semiconductor die containing integrated circuitry and the daughter electrical device is an electrical component or wherein the parent electrical device is an electrical component and the daughter electrical device is a semiconductor die containing integrated circuitry.

5. The enhanced packaged integrated circuit of claim 1, wherein there is a plurality of daughter electrical devices attached to the parent electrical device.

6. The enhanced packaged integrated circuit of claim 1 further comprising in between the passivation layer and the plurality of solder contacts:
a redistributing layer formed over the passivation layer, the redistributing layer containing electrical conductors to permit the routing of electrical signals; and
a second passivation layer applied over the redistributing layer, the second passivation layer to protect the redistributing layer.

7. The enhanced packaged integrated circuit of claim 6, wherein the redistributing layer and the second passivation layer cover all of the bottom surface of the parent electrical device, and wherein the electrical conductors in the redistributing layer are routed throughout the bottom surface of the parent electrical device.

8. The enhanced packaged integrated circuit of claim 6, wherein the redistributing layer covers all of the bottom surface of the parent electrical device except for an area above a bottom surface of the daughter electrical device, and wherein the electrical conductors in the redistributing layer are not routed above the daughter electrical device.

9. The enhanced packaged integrated circuit of claim 1, wherein the daughter electrical device extends beyond the passivation layer, and a bottom surface of the daughter electrical device further comprises a metalized layer to permit attachment to the circuit board.

10. The enhanced packaged integrated circuit of claim 1, wherein the packaged integrated circuit is packaged in a wafer-chip scale package.

11. The enhanced packaged integrated circuit of claim 1, wherein the packaged integrated circuit is packaged in a ball-grid array package.

12. The enhanced packaged integrated circuit of claim 1, wherein the solder contacts are solder bumps, solder balls, land pads, pins, or leads.

13. A method for manufacturing an enhanced packaged integrated circuit, the method comprising:
partially fabricating a parent component, wherein the fabrication stops at a stage prior to a completion of the fabrication of the parent component;
attaching a daughter component onto the parent component, wherein the daughter component is attached to a bottom surface of the parent component via a plurality of solder contacts mounted onto the daughter component;
depositing a first passivation layer over the daughter component and the bottom surface of the parent component; and
completing the fabrication of the parent component.

14. The method of claim 13, wherein the fabrication of the parent component stops prior to a forming of a passivation layer over the parent component.

15. The method of claim 13, wherein the completing comprises:
testing functionality of the parent component; and
placing solder contacts on electrical contact points of the parent component if it passes functional testing.

16. The method of claim 13, wherein the completing comprises:
forming one or more redistributing layers over the first passivation layer, wherein the distributing layer includes electrical conductors, wherein the electrical conductors are used to route electrical signal within or into and out of the enhanced packaged integrated circuit;
depositing a second passivation layer over the redistributing layers;
testing functionality of the parent component; and
placing solder contacts on electrical contact points formed on the redistributing layer if the parent component passes functional testing.

17. The method of claim 13, wherein a plurality of daughter components are attached to the bottom surface of the parent component.

18. The method of claim 13, wherein the parent board and the daughter board are either integrated circuits or passive components.

19. A method for manufacturing an enhanced packaged integrated circuit, the method comprising:
attaching a first component onto a bottom surface of a second component, wherein the first component is attached to the second component via a plurality of electrical contacts mounted onto the first component;
depositing a passivation layer over the first component and the bottom surface of a second component;
testing functionality of the second component; and
placing external electrical contacts on electrical contact points of the second component if the second component passes functional testing.

20. The method of claim 19 further comprising after the depositing:
forming one or more redistributing layers over the passivation layer, wherein the distributing layer includes electrical conductors, wherein the electrical conductors are used to route electrical signals within or into and out of the enhanced packaged integrated circuit; and
depositing a second passivation layer over the redistributing layers.

21. The method of claim 19, wherein a plurality of first components are attached to the second component.

22. The method of claim 19, wherein the first component and the second component are either integrated circuits or passive components.

23. An integrated circuit comprising:
a parent device with a bottom surface having a first plurality of contact pads in a center portion and a second plurality of contact pads in a periphery portion;
a daughter device attached to the bottom surface, the daughter device having a first plurality of contact points electrically coupled to the first plurality of contact pads of the parent device;
a passivation layer to fix the daughter device to the bottom surface; and
a second plurality of contact points electrically coupled to the second plurality of contact pads.

24. The integrated circuit of claim 23 further comprising a layer of electrical conductors electrically coupling contact points from the second plurality of contact points to contact pads in the second plurality of contact pads, the layer of electrical conductors arranged between the passivation layer and a second passivation layer.
